(19) United States
(12) Patent Application Publication
(10) Pub. No.: US 2026/0143862 A1
(43) Pub. Date: May 21, 2026

(54) QUANTUM DOT LAYER, LIGHT-EMITTING ELEMENT, DISPLAY DEVICE, AND METHOD FOR MANUFACTURING LIGHT-EMITTING ELEMENT

(71) Applicant: Sharp Display Technology Corporation, Kameyama City, Mie (JP)

(72) Inventor: Ryo KITAMURA, Sakai City, Osaka (JP)

(21) Appl. No.: 19/118,840

(22) PCT Filed: Oct. 14, 2022
(86) PCT No.: PCT/JP2022/038462

§ 371 Date: Apr. 7, 2025

(51) Int. Cl. H10H 20/812; B82Y 30/00; B82Y 40/00; H10H 20/01; H10H 29/851

(52) U.S. Cl. CPC H10H 20/812; B82Y 30/00; B82Y 40/00; H10H 20/01; H10H 29/8512

(57) ABSTRACT

A quantum dot layer according to the disclosure includes a first quantum dot and a second quantum dot each having a surface, 80% or more of which is occupied by a region constituted by one type of equivalent crystal plane and having a first lattice constant. The quantum dot layer includes a matrix material that fills a space between the first quantum dot and the second quantum dot. The matrix material has a second lattice constant that is from 95% to 105% of the first lattice constant.

### TECHNICAL FIELD

The disclosure relates to a quantum dot layer, a light-emitting element, a display device, and a method for manufacturing a light-emitting element.

### BACKGROUND ART

PTL 1 discloses a luminescent device in which perovskite crystals are encapsulated in an insulating layer.

### CITATION LIST

### Patent Literature

PTL 1: JP 2018-525776 T (published on September 6, 2018)

### SUMMARY OF INVENTION

### Technical Problem

In a light-emitting element including a quantum dot, there has been a problem in that luminous efficiency deteriorates due to a dangling bond (uncombined bond) generated around the quantum dot.

### Solution to Problem

A quantum dot layer according to an aspect of the disclosure includes a first quantum dot and a second quantum dot each having a surface, 80% or more of which is occupied by a region constituted by one type of equivalent crystal plane and having a first lattice constant, and a matrix material filling a space between the first quantum dot and the second quantum dot, the matrix material having a second lattice constant that is from 95% to 105% of the first lattice constant.

A quantum dot layer according to an aspect of the disclosure includes a first quantum dot and a second quantum dot each having a surface, 80% or more of which is occupied by a region constituted by one type of equivalent crystal plane, and a matrix material filling a space between the first quantum dot and the second quantum dot and being lattice-matched at an interface with the region.

A method for manufacturing a light-emitting element according to an aspect of the disclosure includes applying, onto an underlayer, a quantum dot solution including a quantum dot having a surface, 80% or more of which is occupied by a region constituted by one type of equivalent crystal plane and having a first lattice constant, a precursor, and a solvent, and modifying the precursor to cause a matrix material to be epitaxially grown on the region, the matrix material having a second lattice constant that is from 95% to 105% of the first lattice constant.

### Advantageous Effects of Invention

According to an aspect of the disclosure, it is possible to improve luminous efficiency.

### BRIEF DESCRIPTION OF DRAWINGS

FIG. 1 is a cross-sectional view illustrating an example of a structure of a light-emitting element according to an embodiment of the disclosure.

FIG. 2 is a schematic view illustrating an example of a region between quantum dots illustrated in FIG. 1.

FIG. 3 is a schematic view illustrating another example of the region between the quantum dots illustrated in FIG. 1.

FIG. 4 is a diagram illustrating an example of the appearance of a quantum dot having a zinc blende crystal structure in which (100) equivalent planes occupy 80% or more of the surface of the quantum dot.

FIG. 5 is a diagram illustrating an example of the appearance of a quantum dot having a zinc blende crystal structure in which (111) equivalent planes occupy 80% or more of the surface of the quantum dot.

FIG. 6 is a diagram illustrating an example of the appearance of a quantum dot having a zinc blende crystal structure in which (110) equivalent planes occupy 80% or more of the surface of the quantum dot.

FIG. 7 is a diagram illustrating an example of the appearance of a quantum dot having a wurtzite crystal structure in which (11−20) equivalent planes occupy 80% or more of the surface of the quantum dot.

FIG. 8 is a cross-sectional view illustrating a configuration example of a quantum dot layer illustrated in FIG. 1.

FIG. 9 is a cross-sectional view illustrating another configuration example of the quantum dot layer illustrated in FIG. 1.

FIG. 10 is a cross-sectional view illustrating another configuration example of the quantum dot layer illustrated in FIG. 1.

FIG. 11 is a cross-sectional view illustrating another configuration example of the quantum dot layer illustrated in FIG. 1.

FIG. 12 is a diagram illustrating manufacturing of a coating liquid according to Example 1.

FIG. 13 is a diagram illustrating manufacturing of a light-emitting element according to Example 1.

FIG. 14 is a plan view illustrating a configuration example of a display device according to an embodiment of the disclosure.

### DESCRIPTION OF EMBODIMENTS

### First Embodiment

### Configuration of Light-Emitting Element

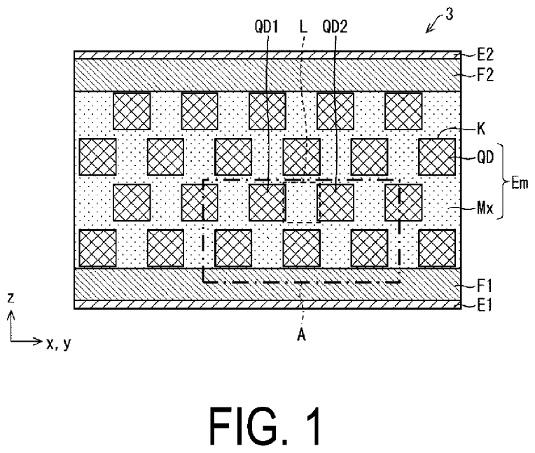

FIG. 1 is a cross-sectional view illustrating a configuration example of a light-emitting element according to an embodiment of the disclosure. As illustrated in FIG. 1, a light-emitting element 3 includes a first electrode E1 and a second electrode E2 facing each other, and a quantum dot layer Em located between the first electrode E1 and the second electrode E2. The quantum dot layer Em may be a light-emitting layer that performs electroluminescence. The light-emitting element 3 may include one or both of a charge function layer F1 located between the first electrode E1 and the quantum dot layer Em and a charge function layer F2 located between the second electrode E2 and the quantum dot layer Em.

The quantum dot layer Em includes a plurality of quantum dots QD including a first quantum dot QD1 and a second quantum dot QD2, and a matrix material Mx that fills a space between the first quantum dot QD1 and the second quantum dot QD2. A region K constituted by one type of equivalent crystal plane and having a first lattice constant occupies 80% or more of each of the surfaces of the first quantum dot QD1 and the second quantum dot QD2. The matrix material Mx has a second lattice constant, and the second lattice constant is from 95% to 105% of the first lattice constant.

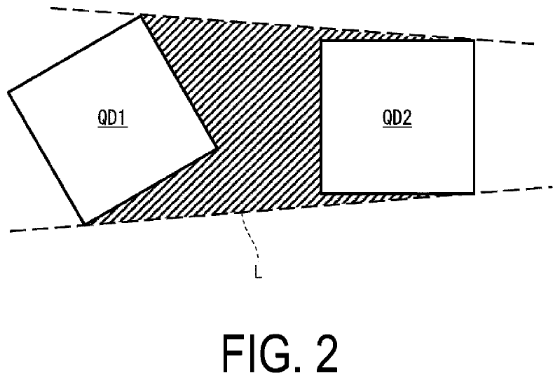

Note that “one type of equivalent crystal plane” is the same in the first quantum dot QD1 and the second quantum dot QD2, and hereinafter, the “region K constituted by one type of equivalent crystal plane and having the first lattice constant” is referred to as an “equivalent region K”. FIG. 1, and FIGS. 2 to 12 described later do not limit the shape of the quantum dot QD. The three-dimensional shape of the quantum dot QD may be any shape, and may be, for example, a substantially spherical shape, a substantially spheroidal shape, a substantially cylindrical shape, a substantially prismatic shape, or a substantially polyhedral shape. The cross-sectional shape of the quantum dot QD may be any shape, and may be, for example, a substantially circular shape, a substantially elliptical shape, a substantially triangular shape, a substantially rectangular shape, a substantially hexagonal shape, or a substantially octagonal shape.

At least one of the first electrode E1 or the second electrode E2 is a transparent electrode. One of the first electrode E1 and the second electrode E2 is an anode and the other is a cathode. Each of the charge function layers F1 and F2 may include any one or more of a charge injection layer, a charge transport layer, and a charge blocking layer.

The matrix material Mx means a member that includes and holds other objects, and can be referred to as a base material, a parent material, or a filler. The matrix material Mx may be solid at room temperature. The matrix material Mx may be a member that includes and holds the first quantum dot QD1 and the second quantum dot QD2. The matrix material Mx may be a constituent element of the quantum dot layer Em including the first quantum dot QD1 and the second quantum dot QD2.

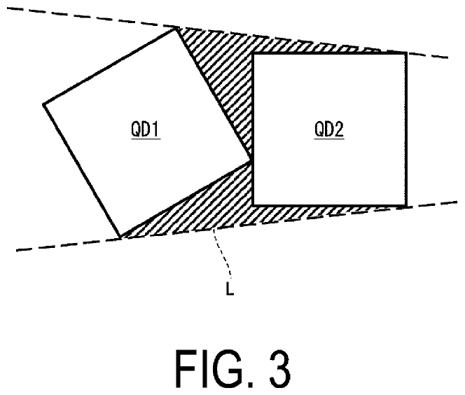

FIG. 2 and FIG. 3 are each a schematic view illustrating an example of a region between the quantum dots illustrated in FIG. 1. The matrix material Mx may be filled in the quantum dot layer Em. As illustrated in FIG. 1, the matrix material Mx may fill regions L (spaces) between the first and second quantum dots QD1 and QD2. As illustrated in FIG. 2 and FIG. 3, in a cross-sectional view, the region L is a region surrounded by two straight lines (external common tangents) circumscribing the outer peripheries of the first and second quantum dots QD1 and QD2, and the outer peripheries (facing outer peripheries) of the first and second quantum dots QD1 and QD2 on the side on which they face each other. As illustrated in FIG. 3, even when the first quantum dot QD1 is close to the second quantum dot QD2, the region L can still exist.

In the quantum dot layer Em, the matrix material Mx may fill regions (spaces) other than a quantum dot group including the first and second quantum dots QD1 and QD2. Note that three or more quantum dots are collectively referred to as a quantum dot group. In the quantum dot layer Em, the matrix material Mx may infill the regions (spaces) other than the quantum dot group including the first and second quantum dots QD1 and QD2. The first and second quantum dots QD1 and QD2 may be embedded in the matrix material Mx at intervals.

Outer edges (upper surface and lower surface) of the quantum dot layer Em may be covered with the matrix material Mx. Alternatively, the matrix material Mx may extend from the outer edges of the quantum dot layer Em, and the quantum dots QD may be positioned away from the outer edges. The outer edges of the quantum dot layer Em need not necessarily be formed only by the matrix material Mx, and part of the quantum dot group may be exposed from the matrix material Mx. The matrix material Mx may indicate a portion of the quantum dot layer Em excluding the quantum dot group including the first and second quantum dots QD1 and QD2.

The matrix material Mx may enclose the first and second quantum dots QD1 and QD2. The matrix material Mx may enclose the quantum dot group including the first and second quantum dots QD1 and QD2. The matrix material Mx may be formed to fill spaces formed between the first and second quantum dots QD1 and QD2. The matrix material Mx may partially or completely fill spaces between quantum dots of the quantum dot group.

The matrix material Mx may include a continuous film having an area equal to or greater than 1000 nm² in a plane direction orthogonal to a layer thickness direction of the quantum dot layer Em. The continuous film means a film not partitioned by a material other than a material constituting the continuous film in one plane. The continuous film may be in the form of an integrated film connected without interruption by chemical bonding of the material constituting the matrix material Mx.

The matrix material Mx may be the same material as that of a shell of the first quantum dot QD1. In this case, an average distance between cores adjacent to each other (core-to-core distance) may be 3 nm or greater, or may be 5 nm or greater. Alternatively, the average distance between the cores adjacent to each other may be 0.5 times or more the average core diameter. The core-to-core distance is an average of distances between adjacent cores in a space including 20 cores. The core-to-core distance may be kept wider than the distance obtained when the shells are in contact with each other. The average core diameter is obtained by averaging the core diameters of 20 cores, in a cross-sectional observation in a space including the 20 cores. The core diameter can be the diameter of a circle having the same area as the core area in the cross-sectional observation.

A concentration of the matrix material Mx in the quantum dot layer Em is, for example, an area ratio occupied by the matrix material Mx in a cross section of the quantum dot layer Em. This concentration may be from 10% to 90%, from 30% to 70% in the cross-sectional observation. This concentration may be measured, for example, from an area ratio in image processing in the cross-sectional observation. When the first quantum dot QD1 has a core-shell structure, the concentration of the shell may be from 1% to 50%. When the shell material and the matrix material are the same (same composition) and the shell and the matrix material Mx are indistinguishable from each other, the concentration of a region including both the matrix material Mx and the shell may be in a numerical range obtained by adding a numerical range of the concentration of the shell to a numerical range of the concentration of the matrix material Mx. The ratios of the core and the shell of the quantum dot QD and the matrix material Mx may be appropriately adjusted so that the total is 100% or less. As described above, when the shell and the matrix material Mx are indistinguishable from each other, the shell may be regarded as part of the matrix material Mx.

The quantum dot layer Em may be constituted by the quantum dot group including the first and second quantum dots QD1 and QD2, and the matrix material Mx. When analyzing the quantum dot layer Em, the intensity of the carbon detected based on the chain structure may be equal to or less than the noise level.

The constituent material of the matrix material Mx is preferably an inorganic material, and preferably has a wider band gap than those of the constituent materials of the first and second quantum dots QD1 and QD2. As the constituent material of the matrix material Mx, a semiconductor or an insulator can be used. Examples of the constituent material of the matrix material Mx include, for example, a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium gallium sulfide (MgGa₂S₄). The metal oxide may be zinc oxide (ZnO), titanium oxide (TiO₂), tin oxide (SnO₂), tungsten oxide (WO₃), and zirconium oxide (ZrO₂). Note that a chemical formula written within parentheses after a compound name is a representative example. In addition, the composition ratio described in the chemical formula is preferably stoichiometric in which the actual composition of the compound is the same as the chemical formula, but need not necessarily be stoichiometric.

The above-described structure of the matrix material Mx need not necessarily be observed over the entire quantum dot layer Em as long as the above-described structure is understood by observing the quantum dot layer Em across a width of approximately 100 nm in a cross-sectional observation of the quantum dot layer Em. The matrix material Mx may include, for example, as an additive, a substance different from the main material (for example, an inorganic substance such as an inorganic semiconductor).

In a quantum dot layer in which organic ligands protect the surface of the quantum dot, there are many voids in the quantum dot layer. Therefore, when the bond between the organic ligand and the quantum dot is lost, the organic ligand is likely to move and there is a high probability that the organic ligand does not recombine. In addition, the organic ligand itself easily deteriorates or decomposes due to light, heat, and current injection. Therefore, a light-emitting layer in which the organic ligands protect the surface of the quantum dot has a problem in durability and reliability. On the contrary, in the quantum dot layer Em according to the disclosure, the matrix material Mx protects the surface of the quantum dot QD, and the quantum dot layer Em is thus excellent in durability and reliability. This is because the matrix material Mx includes a continuous film that is densely formed without voids. Since the matrix material Mx is dense, even if the constituent element of the matrix material Mx loses the bond with the quantum dot QD, the constituent element is unlikely to move and there is a high probability that the constituent element recombines. In addition, this is because the matrix material Mx is made of an inorganic material. An inorganic material is less likely to deteriorate than an organic material.

In addition, using the matrix material Mx, it is possible to improve the exposure resistance of the quantum dot layer against oxygen and water, and also the resistance of the quantum dot layer against a coating liquid, a developer, and the like in a process of forming and patterning an upper layer overlying the quantum dot layer.

The matrix material Mx has a second lattice constant that is the same as or close to the first lattice constant. Thus, the matrix material Mx can be lattice-matched with the first quantum dot QD1 and the second quantum dot QD2 at an interface with the equivalent region K. As described above, the second lattice constant may be from 95% to 105% of the first lattice constant, and more preferably from 98% to 102% of the first lattice constant. The band gap of the matrix material Mx is preferably greater than the band gap of the first quantum dot QD1. The band gap of the matrix material Mx is preferably greater than the band gap of the second quantum dot QD2.

The one type of equivalent crystal plane constituting the equivalent region K is preferably a polar plane. The polar plane is a crystal plane in which a valence of cations and a valence of anions exposed on the surface are not balanced. Specifically, the polar plane is a crystal plane in which the valence of exposed cations is different from the valence of anions, and is a plane that is positively charged and can strongly attract anions, or a plane that is negatively charged and can strongly attract cations. In contrast, a non-polar plane is a crystal plane in which the valence of cations and the valence of anions exposed are balanced. Therefore, the constituent element of the matrix material Mx is more strongly attracted to the equivalent region K when the equivalent region K is constituted by the polar plane than when the equivalent region K is constituted by the non-polar plane. The more strongly the constituent element of the matrix material Mx is attracted to the equivalent region K, the more likely the matrix material Mx undergoes crystal growth so that the crystal lattice of the matrix material Mx is matched with the crystal lattice of the equivalent region K. At least part of the matrix material Mx may be epitaxially grown on the equivalent region K with the equivalent region K being a starting point of the crystal growth.

The first quantum dot QD1 may have a core-shell structure, a shell-less structure, or a multi-shell structure. In a cross-sectional view passing through the core of the first quantum dot QD1, a boundary surface between the core or the shell of the first quantum dot QD1 and a substance occupying the outside of the first quantum dot QD1 may be regarded as the surface of the first quantum dot QD1. For example, when the first quantum dot QD1 has a core-shell structure in which the shell is partially formed on the surface of the core, the surface of the first quantum dot QD1 may include both the boundary surface between the core and the substance and the boundary surface between the shell and the substance. In this case, only the boundary surface between the core and the substance may appear in the cross-section, only the boundary surface between the shell and the substance may appear in the cross-section, or both may appear in the cross-section. For example, when the first quantum dot QD1 has a core-shell structure in which the shell completely covers the core, the surface of the first quantum dot QD1 may include only the boundary surface between the shell and the substance. For example, when the first quantum dot QD1 has a shell-less structure, the surface of the first quantum dot QD1 may include only the boundary surface between the core and the substance. The substance occupying the outside of the first quantum dot QD1 may include the matrix material Mx. The substance occupying the outside of the quantum dot QD1 may further include a substance constituting any one of the charge function layers F1 and F2, the first electrode E1, and the second electrode E2. Similarly to the first quantum dot QD1, the second quantum dot QD2 may also have a core-shell structure, a shell-less structure, or a multi-shell structure.

The crystal structure of the core and the crystal structure of the shell may be the same or different from each other. When a plurality of layers are layered, it is known that, if a given layer is thin (typically, a three-atom layer or less), the crystal structure of that layer usually follows the crystal structure of the lower layer underlying that layer. On the other hand, it is known that, if a given layer is thick, the crystal structure of that layer usually follows one of the crystal structures that can be spontaneously achieved in bulk by the material forming that layer.

The crystal plane of the first quantum dot QD1 can be specified by the following method. The constituent element and the crystal plane of the first quantum dot QD1 can be analyzed by observing the first quantum dot QD1 with an X-ray diffraction (XRD) measuring device, an energy dispersive X-ray spectroscopy (EDS) measuring device, an X-ray photoelectron spectroscopy (XPS) measuring device, an electron energy loss spectroscopy (EELS) measuring device, a transmission electron microscopy (TEM) device, or the like.

The crystal structure of the first quantum dot QD1 may be measured by TEM and an electron diffraction pattern using the TEM. The crystal structure can be identified based on the atomic arrangement and the diffraction pattern observed by high resolution TEM. The composition of the first quantum dot QD1 can be analyzed and determined by EDS or EELS that is used in TEM. This is because a peak specific to the constituent element of the first quantum dot QD1 appears in a spectral result at an intensity ratio corresponding to the composition ratio.

Therefore, the composition of the first quantum dot QD1 and the interplanar spacing between each of the crystal planes can be specified. Then, by comparing the specified value with the interplanar spacing between each of the crystal planes obtained by the TEM observation, the plane index, lattice constant, and area ratio of each region occupying the surface of the first quantum dot QD1 can be calculated.

The second quantum dot QD2 and the matrix material Mx can also be analyzed by the same method as that of the first quantum dot QD1. The first quantum dot QD1, the second quantum dot QD2, and the matrix material Mx may be analyzed by another method.

Normally, the configuration of the quantum dot layer Em is random, and uniform regardless of the location. More specifically, the quantum dot layer Em is uniform regardless of the location with respect to the composition, shape, crystal structure, plane index of the quantum dot QD, the proportion of the equivalent region K occupying the surface of the quantum dot QD, and the composition and crystal structure of the matrix material Mx. Therefore, the result of an analysis performed on a portion of the quantum dot layer Em may be applied to the entire quantum dot layer Em.

Normally, when the first quantum dot QD1 in the matrix material Mx is analyzed, even when the quantum dot QD is used for which the equivalent region K occupies substantially 100% of the surface thereof, the calculated value of the area ratio occupied by the equivalent region K tends to be 80% or more and less than 100% due to analysis accuracy, measurement limitation, blurring caused by the presence of the matrix material Mx, and the like. Therefore, when the calculated area ratio of the equivalent region K is 80% or more, it is considered highly probable that the equivalent region K occupies substantially 100% of the surface of the first quantum dot QD1. In addition, when the calculated area ratio of the equivalent region K is 60% or more, it is considered highly probable that the equivalent region K occupies 80% of the surface of the first quantum dot QD1.

### Miller Plane Indices

In the disclosure, Miller plane indices are used to specify crystal planes. That is, with respect to crystals other than a hexagonal crystal, given unit lattice vectors a₁, a₂, a₃ and integers h, k, 1, a crystal plane passing through three points specified by 1/h * vector a₁, 1/k*vector a₂, and 1/1*vector a₃ is referred to as an (hkl) plane. Further, with respect to the hexagonal crystal, given further a unit lattice vector a₄ defined by a₄:=−a₁ −a₂ and an integer i defined by i:=−h−k, a crystal plane passing through the above-described three points is referred to as an (hkil) plane.

In this specification, with respect to the crystals other than the hexagonal crystal, the (hkl) plane and planes equivalent to the (hkl) plane are collectively referred to as (hkl) equivalent planes. Further, with respect to the hexagonal crystal, the (hkil) plane and planes equivalent to the (hkil) plane are collectively referred to as (hkil) equivalent planes.

### First Combination of Quantum Dot and Base Material

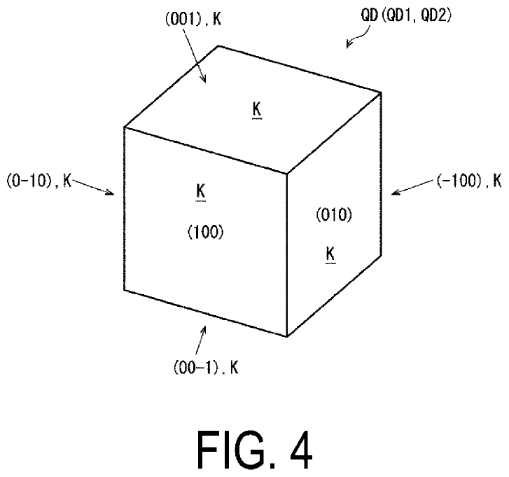

FIG. 4 is a diagram illustrating an example of the appearance of a quantum dot having a zinc blende crystal structure in which (100) equivalent planes occupy 80% or more of the surface of the quantum dot. As illustrated in FIG. 4, the quantum dot QD having the zinc blende crystal structure includes a (100) plane, a (−100) plane, a (010) plane, a (0−10) plane, a (001) plane, and a (00−1) plane, and these six planes are equivalent to each other. In the disclosure, these six planes are referred to as (100) equivalent planes. In the zinc blende quantum crystal structure, the (100) equivalent planes are polar planes. A typical shape of the quantum dot QD having the zinc blende crystal structure in which the (100) equivalent planes occupy 100% of the surface is a rectangular parallelepiped.

For example, the equivalent region K may include ZnS having a zinc blende crystal structure, and an equivalent crystal plane constituting the equivalent region K may be the (100) equivalent plane. In this example, the matrix material Mx may include one or more of ZnS, Y₂O₃, Si, Zn₃P₂, GaAs, GaP, SiC, Cu₂ ZnSnS₄, CuInS₂, GaN, and ZnMgSe. The matrix material may include a mixed crystal including two or more of these substances.

As another example, the equivalent region K may include ZnSe having a zinc blende crystal structure, and an equivalent crystal plane constituting the equivalent region K may be the (100) equivalent plane. In this example, the matrix material Mx may include one or more of ZnSe, GaAs, and Al₂O₃. The matrix material may include a mixed crystal including two or more of these substances.

### Second Combination of Quantum Dot and Base Material

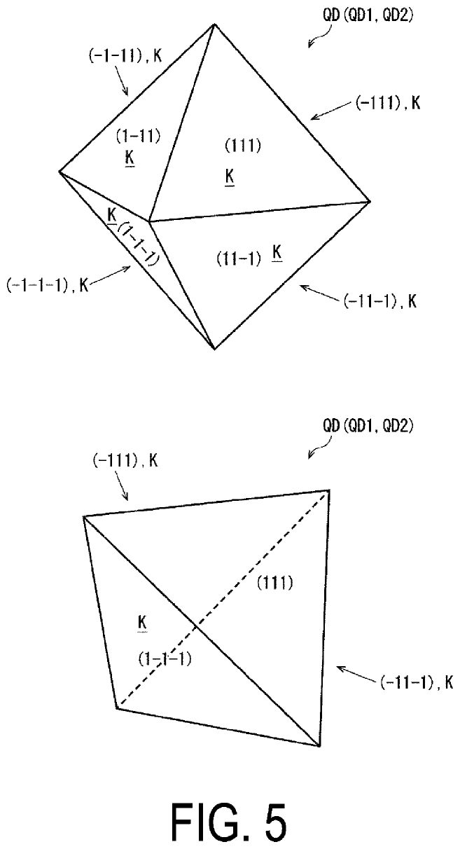

FIG. 5 is a diagram illustrating an example of the appearance of a quantum dot having a zinc blende crystal structure in which (111) equivalent planes occupy 80% or more of the surface of the quantum dot. As illustrated in FIG. 5, the quantum dot QD having the zinc blende crystal structure includes a (111) plane, a (−111) plane, a (1−11) plane, a (−1−11) plane, a (11−1) plane, a (−11−1) plane, a (1−1−1) plane, and a (−1−1−1) plane, and these eight planes are equivalent to each other. In the disclosure, these eight planes are referred to as (111) equivalent planes. In the zinc blende crystal structure, the (111) equivalent planes are polar planes. Typical shapes of the quantum dot QD having a zinc blende crystal structure in which the (111) equivalent planes occupy 100% of the surface are an octahedron and a tetrahedron.

As an example, the equivalent region K may include ZnS having a zinc blende crystal structure, and an equivalent crystal plane constituting the equivalent region K may be the (111) equivalent plane. In this example, the matrix material Mx may include one or more of Si, SiC, and CeO₂. The matrix material may include a mixed crystal including two or more of these substances.

### Third Combination of Quantum Dot and Base Material

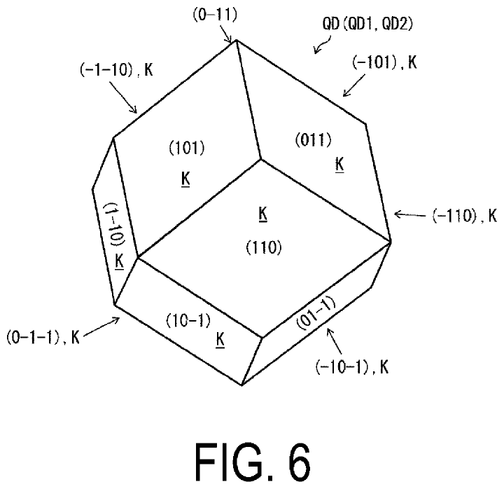

FIG. 6 is a diagram illustrating an example of the appearance of a quantum dot having a zinc blende crystal structure in which (110) equivalent planes occupy 80% or more of the surface of the quantum dot. As illustrated in FIG. 6, the quantum dot QD having the zinc blende crystal structure includes a (110) plane, a (011) plane, a (101) plane, a (1−10) plane, a (01−1) plane, a (−101) plane, a (31 110) plane, a (0−11) plane, a (101) plane, a (−1−10) plane, a (0−1−1) plane, and a (−10−1) plane, and these twelve planes are equivalent to each other. In the disclosure, these twelve planes are referred to as (110) equivalent planes. In the zinc blende crystal structure, the (110) equivalent planes are non-polar planes. A typical shape of the quantum dot QD having a zinc blende crystal structure in which the (110) equivalent planes occupy 100% of the surface is a dodecahedron.

As an example, the equivalent region K may include ZnS having a zinc blende crystal structure, and an equivalent crystal plane constituting the equivalent region K may be the (110) equivalent plane. In this example, the matrix material Mx may include one or more of Si and CeO₂. The matrix material may include a mixed crystal including these two substances.

### Fourth Combination of Quantum Dot and Base Material

The appearance of the quantum dot QD having a sodium chloride crystal structure in which (111) equivalent planes occupy 80% or more of the surface of the quantum dot QD is similar to the appearance of the quantum dot having the zinc blende crystal structure in which (111) equivalent planes occupy 80% or more of the surface of the quantum dot. With reference to FIG. 5, the quantum dot QD having the sodium chloride crystal structure includes (111) equivalent planes, and in the sodium chloride crystal structure, the (111) equivalent planes are polar planes.

As an example, the equivalent region K may include PdS having a sodium chloride crystal structure, and an equivalent crystal plane constituting the equivalent region K may be the (111) equivalent plane. In this example, the matrix material Mx may include one or more of InP and CsPdBr₃. The matrix material may include a mixed crystal including these two substances.

### Fifth Combination of Quantum Dot and Base Material

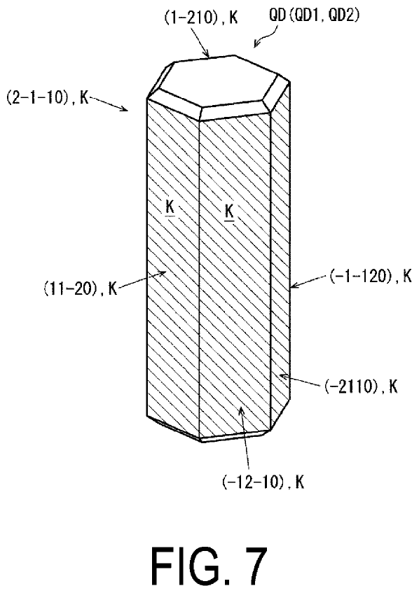

FIG. 7 is a diagram illustrating an example of the appearance of a quantum dot having a wurtzite crystal structure in which (11−20) equivalent planes occupy 80% or more of the surface of the quantum dot. As illustrated in FIG. 7, the quantum dot QD having the wurtzite crystal structure includes a (11−20) plane, a (−1−120) plane, a (1−210) plane, a (−12−10) plane, a (2−1−10) plane, and a (−2110) plane, and these six planes are equivalent to each other. In the disclosure, these six planes are referred to as (11−20) equivalent planes. In the wurtzite crystal structure, the (11−20) equivalent planes are non-polar planes. A typical shape of the quantum dot QD having the wurtzite crystal structure in which the (11−20) equivalent planes occupy 80% or more of the surface is a hexagonal column.

As an example, the equivalent region K may include ZnS having a wurtzite crystal structure, and an equivalent crystal plane constituting the equivalent region K may be the (11−20) equivalent plane. In this example, the matrix material Mx may include one or more of ZnS, ZnO, ZnSe, ZnTe. The matrix material may include a mixed crystal including two or more of these substances.

### First Configuration Example of Quantum Dot Layer

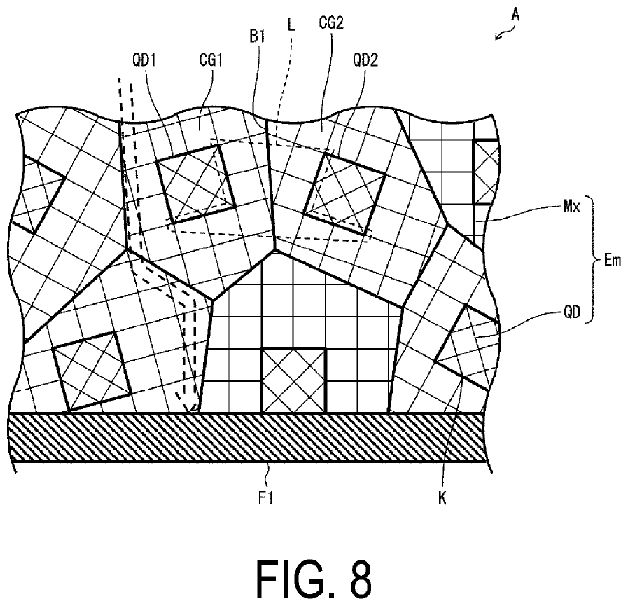

FIG. 8 is a cross-sectional view illustrating a configuration example of the quantum dot layer illustrated in FIG. 1, and correspond to a partial enlarged cross-sectional view obtained by enlarging a portion indicated by the circle A in FIG. 1. As illustrated in FIG. 8, the matrix material Mx includes a first single crystal portion CG1 and a second single crystal portion CG2. The first single crystal portion CG1 is a single crystal in contact with the first quantum dot QD1, and the second single crystal portion CG2 is a single crystal in contact with the second quantum dot QD2. The matrix material Mx protects the surfaces of the first quantum dot QD1 and the second quantum dot QD2.

Note that, as described above, FIG. 8 does not limit the shape of the quantum dot QD. The cross-sectional shape of the quantum dot QD may be any shape, and may be, for example, a substantially circular shape, a substantially elliptical shape, a substantially triangular shape, a substantially rectangular shape, a substantially hexagonal shape, or a substantially octagonal shape. In addition, FIG. 8 does not limit the shapes of single crystal portions such as the first single crystal portion CG1 and the second single crystal portion CG2.

The first single crystal portion CG1 is a single crystal epitaxially grown from the surface of the first quantum dot QD1, and is substantially lattice-matched with the first quantum dot QD1. Therefore, in the configuration according to the disclosure, there are fewer lattice defects or dangling bonds between the first quantum dot QD1 and the first single crystal portion CG1 than in a configuration in which the single crystal portion is not lattice-matched with the quantum dot. The second single crystal portion CG2 is a single crystal epitaxially grown from the surface of the second quantum dot QD2. Therefore, similarly, there are few lattice defects between the second quantum dot QD2 and the second single crystal portion CG2. Since the number of lattice defects is small, non-emitting recombination at a defect level is reduced, and the luminous efficiency of the quantum dot layer Em is improved. In addition, since charge traps due to lattice defects are reduced, the electrical resistivity of the quantum dot layer Em is reduced, and the drive voltage and heat generation of the light-emitting element 3 can thus be reduced.

A mismatched plane B1 is generated between the first single crystal portion CG1 and the second single crystal portion CG2. In the mismatched plane B1, at least one of the crystal lattice or the crystal orientation is mismatched, and there are many lattice defects or dangling bonds. Normally, the mismatched plane B1 is away from the surface of the first quantum dot QD1 and is located at a position at which the influence on the excitons of the core is small. For this reason, a defect level due to the mismatched plane B1 between the first single crystal portion CG1 and the second single crystal portion CG2 does not significantly adversely affect the improvement of the luminous efficiency of the quantum dot layer Em. Therefore, the drive voltage and heat generation of the light-emitting element 3 can be reduced.

### Second Configuration Example of Quantum Dot Layer

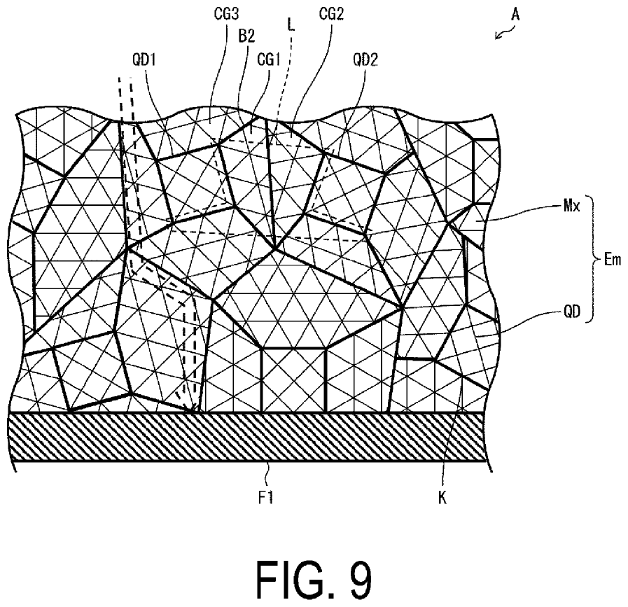

FIG. 9 is a cross-sectional view illustrating another configuration example of the quantum dot layer illustrated in FIG. 1, and correspond to a partial enlarged cross-sectional view obtained by enlarging the portion indicated by the circle A in FIG. 1. As illustrated in FIG. 9, the matrix material Mx may include a third single crystal portion CG3. The third single crystal portion CG3 is in contact with the first quantum dot QD1. The third single crystal portion CG3 is a single crystal epitaxially grown from the surface of the first quantum dot QD1, and is substantially lattice-matched with the first quantum dot QD1. The surface on which the third single crystal portion CG3 has grown is different from the surface on which the first single crystal portion CG1 has grown, and the third single crystal portion CG3 is lattice-mismatched with the first single crystal portion CG1.

Note that, as described above, FIG. 9 does not limit the shape of the quantum dot QD. The cross-sectional shape of the quantum dot QD may be any shape, and may be, for example, a substantially circular shape, a substantially elliptical shape, a substantially triangular shape, a substantially rectangular shape, a substantially hexagonal shape, or a substantially octagonal shape. In addition, FIG. 9 does not limit the shapes of single crystal portions such as the first single crystal portion CG1, the second single crystal portion CG2, and the third single crystal portion CG3.

In a case in which the crystal structure of the surface of the first quantum dot QD1 is different from the crystal structure of the matrix material Mx, even when the combination allows the epitaxial growth of the matrix material Mx, lattice matching may not be established at corner portions of the first quantum dot QD1. Then, a mismatched plane B2 extending from the corner portion of the first quantum dot QD1 is generated. Normally, the corner portions of the first quantum dot QD1 are positions, on the surface of the first quantum dot QD1, that are farthest from the core and have small influence on the excitons of the core. For this reason, a defect level due to lattice-mismatching at the mismatched plane B2 between the first single crystal portion CG1 and the third single crystal portion CG3 does not significantly adversely affect the improvement of the luminous efficiency of the quantum dot layer Em. Therefore, in the same manner as in the first configuration example described above, in this configuration example as well, the luminous efficiency of the quantum dot layer Em is improved, and the drive voltage and heat generation of the light-emitting element 3 can thus be reduced.

### Third Configuration Example of Quantum Dot Layer

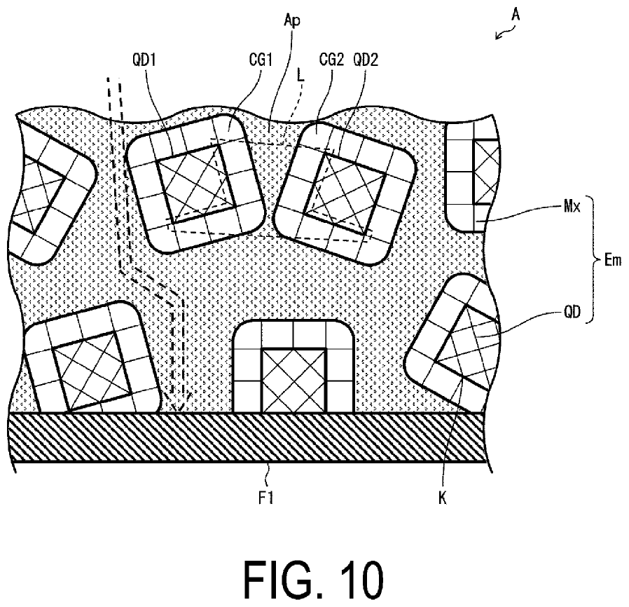

FIG. 10 is a cross-sectional view illustrating another configuration example of the quantum dot layer illustrated in FIG. 1, and correspond to a partial enlarged cross-sectional view obtained by enlarging the portion indicated by the circle A in FIG. 1. As illustrated in FIG. 10, the matrix material Mx may include an amorphous body Ap. At least a portion of the amorphous body Ap is located between the first single crystal portion CG1 and the second single crystal portion CG2.

Note that, as described above, FIG. 10 does not limit the shape of the quantum dot QD. The cross-sectional shape of the quantum dot QD may be any shape, and may be, for example, a substantially circular shape, a substantially elliptical shape, a substantially triangular shape, a substantially rectangular shape, a substantially hexagonal shape, or a substantially octagonal shape. In addition, FIG. 10 does not limit the shapes of single crystal portions such as the first single crystal portion CG1 and the second single crystal portion CG2.

Heat treatment for forming the matrix material Mx may be adjusted in consideration of thermal degradation of layers other than the quantum dots QD and the quantum dot layer Em. For example, the temperature of the heat treatment may be lowered, or the time of the heat treatment may be shortened. As a result, of the matrix material Mx, only a portion thereof in the vicinity of the surface of the quantum dot QD may epitaxially grow, and other portions may become the amorphous body Ap. It is considered that the precursor is preferentially decomposed on the surface of the quantum dot QD on which the matrix material Mx can epitaxially grow, and the matrix material Mx can thus epitaxially grow even under heat treatment conditions under which crystal growth of the matrix material Mx is difficult. The surface of the first quantum dot QD1 is protected by the first single crystal portion CG1, and the surface of the second quantum dot QD2 is protected by the second single crystal portion CG2. Therefore, in the same manner as in the first and second configuration examples described above, in this configuration example as well, the luminous efficiency of the quantum dot layer Em is improved, and the drive voltage and heat generation of the light-emitting element 3 can thus be reduced.

As indicated by the broken line arrows in FIGS. 8, 9, 10, and 11, when the light-emitting element 3 emits light, a leakage current may be present that passes through only the matrix material Mx without charge injection into the quantum dots QD. This leakage current does not contribute to light emission. The density of lattice defects in the amorphous body Ap is higher than the density of lattice defects in the single crystal portion of the matrix material. Due to charge traps caused by lattice defects, the electrical resistivity of the amorphous body Ap may be higher than the electrical resistivity of the single crystal portion of the matrix material. Therefore, the electrical resistance value of a path through which the leakage current flows can be made higher in this configuration example than in the first and second configuration examples describe above and a fourth configuration example described later. As a result of the increased resistance, the leakage current can be reduced. In addition, since the temperature of the heat treatment is low or the time of the heat treatment is short, thermal degradation of the quantum dots QD is small.

By reducing the leakage current and reducing the thermal degradation of the quantum dots QD, the luminous efficiency of the quantum dot layer Em is further improved, and the drive voltage and heat generation of the light-emitting element 3 can thus be further reduced.

### Fourth Configuration Example of Quantum Dot Layer

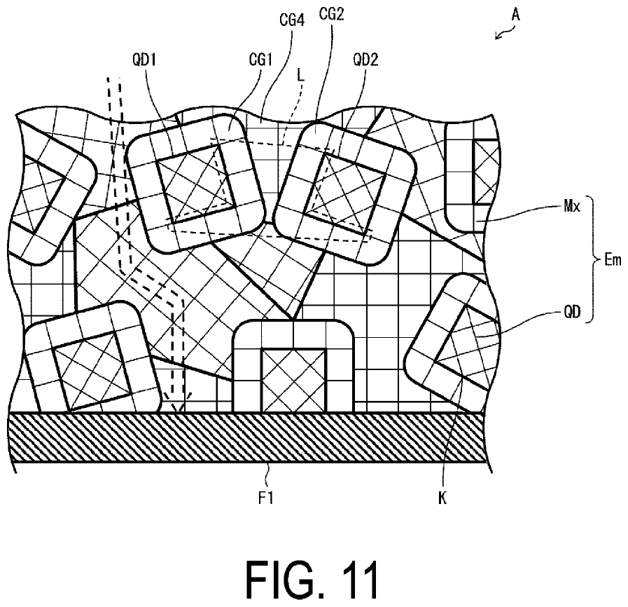

FIG. 11 is a cross-sectional view illustrating another configuration example of the quantum dot layer illustrated in FIG. 1, and correspond to a partial enlarged cross-sectional view obtained by enlarging the portion indicated by the circle A in FIG. 1. As illustrated in FIG. 11, the matrix material Mx may include a fourth single crystal portion CG4. The fourth single crystal portion CG4 is not in contact with any of the plurality of quantum dots QD, and is located between the first single crystal portion CG1 and the second single crystal portion CG2. The fourth single crystal portion CG4 is lattice-mismatched with the first single crystal portion CG1 and the second single crystal portion CG2.

Note that, as described above, FIG. 11 does not limit the shape of the quantum dot QD. The cross-sectional shape of the quantum dot QD may be any shape, and may be, for example, a substantially circular shape, a substantially elliptical shape, a substantially triangular shape, a substantially rectangular shape, a substantially hexagonal shape, or a substantially octagonal shape. In addition, FIG. 11 does not limit the shapes of single crystal portions such as the first single crystal portion CG1, the second single crystal portion CG2, and the fourth single crystal portion CG4.

### Method for Manufacturing Quantum Dot

Examples of a method for manufacturing the quantum dot QD include a heating method, hot injection, a microwave-assisted method, and a continuous flow method. These manufacturing methods will now be described.

### Heating Method

The heating method is a technique of synthesizing each layer of the quantum dot QD by mixing a material in an organic solvent and heating the mixture to thermally decompose and react the material. In the heating method, an organometallic compound is used. The compound is obtained by using trioctylphosphine (TOP) or trioctylphosphine oxide (TOPO) as the organic solvent and bonding dimethylcadmium as a group II raw material with desired elements such as, for example, a TOP complex of S, Se and Te, or a methyl group or an ethyl group, as a group VI raw material. Each layer of the quantum dot QD can be synthesized by mixing the group II and group VI raw materials in the organic solvent, heating the mixture to about 300° C. to thermally decompose the raw materials, and maintaining a high degree of supersaturation of the group II and group VI elements in the organic solvent to promote a reaction of the group II-VI compound.

### Hot Injection

The hot injection is a technique of rapidly injecting raw materials into a heated organic solvent, thereby utilizing supersaturation in the vicinity of the injection region to generate uniform crystal growth nuclei at a high density. In the hot injection, as the raw materials, TOP or T-TOPO is used as the organic solvent and is heated to about 300° C., and group II and group VI raw materials are rapidly injected into the organic solvent to rapidly increase local supersaturation around the injection region and generate uniform crystal growth nuclei at a high density. With the high degree of supersaturation localized in the vicinity of the injection region, the raw materials consumed by the growth of the growth nuclei are supplied at any time by diffusion from the surrounding region having a low degree of supersaturation due to the concentration gradient, and the growth of the quantum dots continues. In this technique, alkylphosphine and trioctylphosphine or an alkylphosphine oxide such as trioctylphosphine oxide, a long-chain carboxylic acid such as oleic acid, and a long-chain amine such as oleamine are added as surfactants or ligands that prevent quantum dot aggregation due to the high density of nucleation.

### Microwave-Assisted Method

The microwave-assisted method is a technique of selectively heating growth raw materials by utilizing microwaves. In this technique, since heating is selective, the controllability of the reaction is favorable. It is thus possible to increase the temperature in a short period of time to a temperature range required for the reaction. In addition, compared with the injection method, the quantum dots can be easily synthesized, even in the atmosphere. Microwaves are selectively resonantly absorbed by molecules having polarization, and therefore, for example, when a chalcogenide suitable for the wavelength of the microwaves is used as a raw material, the raw material can be selectively heated, and it is thus possible to control the growth of the quantum dots. Because of this feature, the raw materials are required to have polarization, and thus, raw materials different from those in the first and second techniques described above are used. Examples of the raw materials include a mixed solution of cadmium stearate, an alkane solvent, and a group VI powder.

### Continuous Flow Method

The continuous flow method is a technique of causing a nucleation reaction and a growth reaction to occur in different reactors by conducting a reaction of raw materials while producing a flow of an organic solvent mixed with the raw materials. With the nucleation reaction and the growth reaction occurring in different reactors, an appropriate temperature gradient can be precisely set, and each reaction can be precisely controlled. This technique is suitable for mass production, offering relatively easy control of crystal growth. In the continuous flow method as well, the quantum dots QD can be grown either in an organic solution or in a gas phase including vapor of an organic solution as described in the three manufacturing methods above. In the continuous flow method, the nucleation and growth reaction can be precisely controlled in separate reactors by mixing an organic solvent with group II and group VI raw materials, moving the raw materials following the flow of the liquid phase or the gas phase, and setting a temperature gradient suitable for the nucleation stage, which is the starting point of growth of the quantum dots QD, and the crystal growth stage. Conditions suitable for each stage can be precisely and independently controlled by separating nucleation and crystal growth into individual vessels and carrying out transport in a liquid or vapor stream between the vessels.

In crystal growth, it is important to maintain a high degree of supersaturation in the raw materials, which is a driving force for nucleation and crystal growth, and, for example, the four types of manufacturing techniques described above have been developed because of differences in the technique for realizing and maintaining such a condition.

To synthesize the quantum dot QD, it is necessary to control synthesis conditions when synthesizing each layer of the quantum dot QD. Examples of methods for selectively causing specific crystal planes to appear as described above include, in the process of synthesizing each layer, controlling, within a specific range, the pH (hydrogen ion concentration) of the solvent in which the materials are mixed. For example, it was experimentally found that the pH of the solvent should be maintained in a range of 9 to 11 in order for the surface of the quantum dot QD to have a zinc blende crystal structure and to have a shape terminating only at the (111) equivalent plane and/or the (100) equivalent plane, both of which are polar planes. The pH in this range is weakly basic with an H⁺concentration higher than that of a neutral condition of pH=7, which suggests that an intermediate reaction between H⁺and the raw materials is involved in the mechanism of preferentially forming specific crystal planes.

In addition, as another method, for example, in a case in which group II-VI crystals such as ZnS and CdS or group III-V crystals such as InN and InP are used, it has been found that (111) equivalent planes appear as a result of relatively decreasing the group VI or group V raw materials. This is because, as the group V or group VI raw materials are decreased, the number of non-bonding orbitals on the (111) equivalent planes, which have a high surface density of bonding orbitals, relatively increases.

In addition, as another method, it has been found that, by adding organic ligands, which are strongly bonded to a crystal plane that is desired to appear, to an organic solvent in which raw materials are mixed, the crystal plane that is desired to appear is stabilized and crystal growth is preferentially performed on other crystal planes. As a result, the crystal plane that is desired to appear can occupy 80% or more of the surface of the quantum dot QD. For example, when the surface of the quantum dot QD has a zinc blende crystal structure, by adding neutral ligands that are strongly bonded to non-polar planes, crystal growth is preferentially promoted on the (111) equivalent plane and the (100) equivalent plane, which are polar planes, and the (110) equivalent plane, which is a non-polar plane, appears.

It is considered that the bonding between the surface of the quantum dot QD during growth and the organic ligand is temporary, and in the organic solvent, an equilibrium state is established in which the ligand repeats desorption and bonding.

Therefore, when the solution temperature is increased, the rate of desorption and bonding increases, and the raw material easily accesses the entire surface of the quantum dot QD. As a result, atoms are preferentially deposited on a crystal plane having a large number of dangling bonds and a great surface energy. For example, when a CdS shell of the quantum dot QD is synthesized at 275° C. or higher, atoms are preferentially deposited on the (111) equivalent plane having a great dangling bond density, and the (100) equivalent plane appears on the surface of the quantum dot QD.

### Example 1

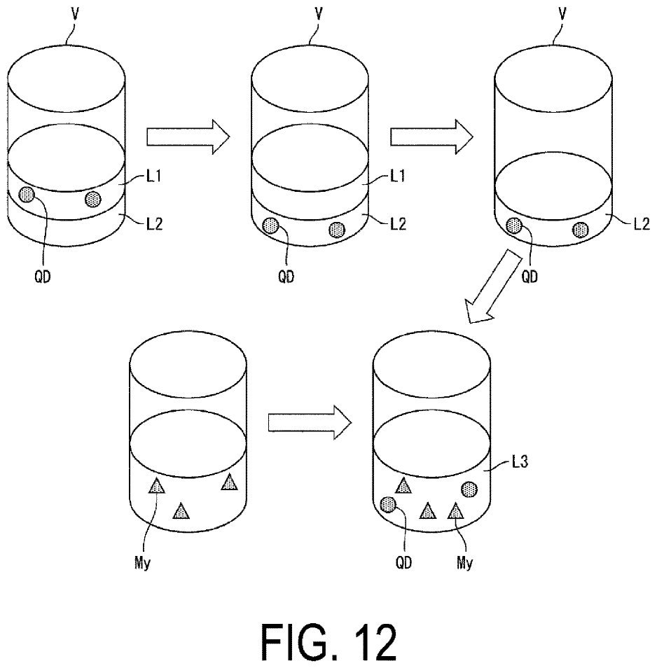

FIG. 12 is a diagram illustrating a method for manufacturing a coating liquid according to Example 1. As illustrated in FIG. 12, ligands to be bonded to the quantum dot QD were replaced. Normally, when the quantum dot QD is synthesized, organic ligands are bonded to the quantum dot QD, and the quantum dots QD are dispersed in a non-polar solvent. The quantum dot dispersion included the quantum dots QD of 10 mg and hexane of 1 mL. The concentration of the quantum dots QD in the quantum dot
dispersion was 10 mg/mL. The quantum dot QD included ZnS having a zinc blende crystal structure in the equivalent region K, and the equivalent crystal plane constituting the equivalent region K was the (100) equivalent plane. The exchange liquid was a solution obtained by mixing a ZnCl solution of 7.5 mL and an EtXanK solution of 2.5 mL. The solvent for the two solutions was NMF. The concentration of the ZnCl solution was 0.2 M, that is, 27.2 mg/mL. The concentration of the EtXanK solution was 0.2 M, that is, 32 mg/mL. Here, “NMF” is an abbreviation for N-methyl formaldehyde, “EtXanK” is an abbreviation for ethyl xanthic acid, and “M” is an abbreviation for mol/L.

The quantum dot dispersion and the exchange liquid were put into one container V. The two liquids were not mixed, and the quantum dot dispersion was located in an upper layer L1 and the exchange liquid was located in a lower layer L2. The two liquids were continuously and vigorously stirred overnight. As a result of the stirring, the quantum dots QD moved from the upper layer L1 to the lower layer L2. The stirred liquid was centrifuged at the rate of 2000 rpm for three minutes, and the lower layer L2 was removed. In the extracted lower layer L2, chloride ions are bonded to the quantum dots QD as inorganic ligands.

Subsequently, ethylacetate was added to the extracted lower layer L2 to precipitate the quantum dots QD, the solvent was removed, and the quantum dots QD were extracted. Then, the extracted quantum dots QD were dispersed in a solution in which a precursor My of the matrix material Mx was dissolved. The matrix material Mx was Y₂O₃. The precursor My was Y(NO₃)₃. The solvent of the solution in which the precursor My was dissolved was a polar solvent, and was DMF. The solution in which the precursor My was dissolved included ZnCl at the concentration of 0.05 M. Here, “DMF” is an abbreviation for dimethyl formaldehyde.

In the above-described manner, a quantum dot solution L3 for forming the quantum dot layer Em was produced (step S1). The quantum dot solution L3 included Y(NO₃)₃ as the precursor My of the matrix material Mx, and DMF as the solvent.

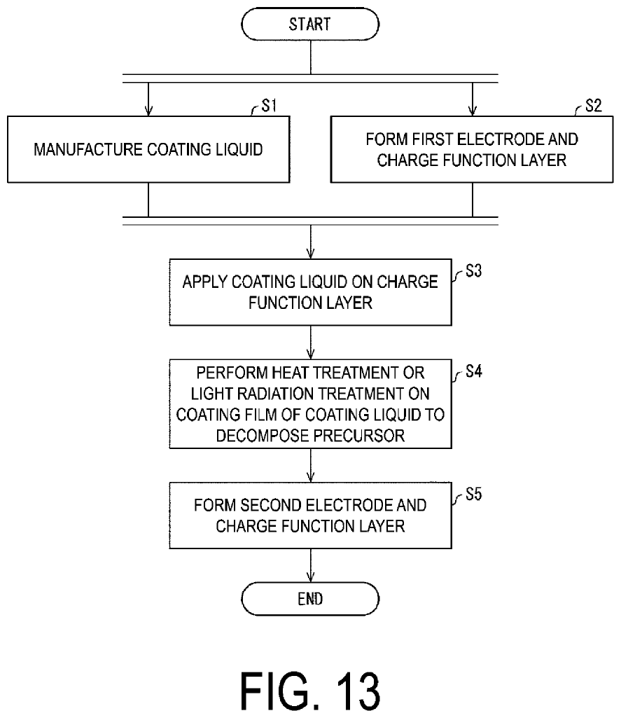

FIG. 13 is a diagram illustrating a method for manufacturing a light-emitting element according to Example 1. As illustrated in FIG. 13, the first electrode E1 and the charge function layer F1 were formed (step S2). The quantum dot solution L3 was applied onto the charge function layer F1 (underlayer) (step S3). A coating film of the quantum dot solution L3 was subjected to heat treatment or light radiation treatment to decompose and modify the precursor My (step S4). In the coating film, Y(NO₃)₃ was decomposed and modified, and Y₂O₃ was epitaxially grown on the (100) equivalent plane of the quantum dot QD. Then, the charge function layer F2 and the second electrode E2 were formed (step S5).

### Second Embodiment

Another embodiment of the disclosure will be described below. Note that, for convenience of description, members having the same functions as those of the members described in the above-described embodiment will be denoted by the same reference numerals and signs, and the description thereof will not be repeated.

Regardless of the relationship between the first lattice constant of the equivalent region K and the second lattice constant of the matrix material Mx, the matrix material Mx is lattice-matched with the first quantum dot QD1 and the second quantum dot QD2 at the interface with the equivalent region K. That is, the quantum dot layer Em includes the first quantum dots QD1, the second quantum dots QD2, and the matrix material Mx, a region constituted by one type of equivalent crystal plane occupies more than half, 80% or more, 90% or more, or more preferably 95% or more of each of the surfaces of the first quantum dot QD1 and the second quantum dot QD2, and the matrix material Mx is lattice-matched at the interface with the above-described region.

### Third Embodiment

Another embodiment of the disclosure will be described below.

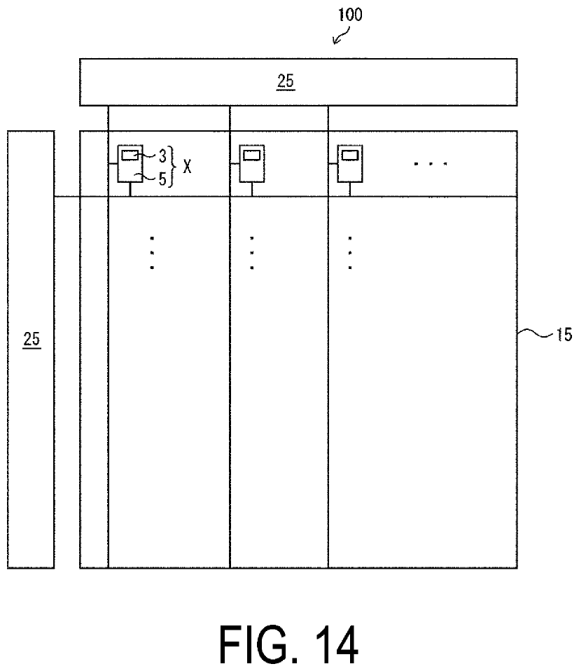

FIG. 14 is a plan view illustrating a configuration example of a display device according to an embodiment of the disclosure. As illustrated in FIG. 14, a display device 100 includes a display portion 15 including a plurality of subpixels X, and a driver circuit 25 that drives the display portion 12. For example, the subpixel X includes the light-emitting element 3 described in the first or second embodiment, and a pixel circuit 5.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### REFERENCE SIGNS LIST

3 Light-emitting element
100 Display device
Ap Amorphous body
CG1 First single crystal portion
CG2 Second single crystal portion
K Region, equivalent region
L3 Quantum dot solution
Mx Matrix material
My Precursor
QD1 First quantum dot
QD2 Second quantum dot

1. A quantum dot layer comprising:
a first quantum dot and a second quantum dot each having a surface, 80% or more of which is occupied by a region constituted by one type of equivalent crystal plane and having a first lattice constant; and
a matrix material filling a space between the first quantum dot and the second quantum dot, the matrix material having a second lattice constant that is from 95% to 105% of the first lattice constant,
wherein the first quantum dot has a core-shell structure.

2. The quantum dot layer according to claim 1,
wherein the second lattice constant is from 98% to 102% of the first lattice constant.

3. The quantum dot layer according to claim
wherein a band gap of the matrix material is greater than a band gap of a core of the first quantum dot.

4. The quantum dot layer according to claim 1,
wherein the equivalent crystal plane is a polar plane.

5. (canceled)

6. The quantum dot layer according to claim 1,
wherein the surface of the first quantum dot includes one or both of a boundary surface between a core of the first quantum dot and a substance occupying the outside of the first quantum dot and a boundary surface between a shell of the first quantum dot and the substance.

7. The quantum dot layer according to claim 1,
wherein a portion of the matrix material is epitaxially grown on the region.

8. The quantum dot layer according to claim 1,
wherein ZnS having a zinc blende crystal structure is included in the region,
the equivalent crystal plane is a (100) equivalent plane, and
the matrix material includes one or more of ZnS, Y₂O₃, Si, Zn₃P₂, GaAs, GaP, SiC, Cu₂ZnSnS₄, CuInS₂, GaN, and ZnMgSe.

9. The quantum dot layer according to claim 1,
wherein ZnSe having a zinc blende crystal structure is included in the region,
the equivalent crystal plane is a (100) equivalent plane, and
the matrix material includes one or more of ZnSe, GaAs, and Al₂O₃.

10. The quantum dot layer according to claim 1,
wherein ZnS having a zinc blende crystal structure is included in the region,
the equivalent crystal plane is a (111) equivalent plane, and
the matrix material includes one or more of Si, SiC, and CeO₂.

11. The quantum dot layer according to claim 1,
wherein ZnS having a zinc blende crystal structure is included in the region,
the equivalent crystal plane is a (110) equivalent plane, and
the matrix material includes one or more of Si and CeO₂.

12. The quantum dot layer according to claim 1,
wherein PdS having a sodium chloride crystal structure is included in the region,
the equivalent crystal plane is a (111) equivalent plane, and
the matrix material includes one or more of InP and CsPdBr₃.

13. The quantum dot layer according to claim 1,
wherein ZnS having a wurtzite crystal structure is included in the region,
the equivalent crystal plane is a (11−20) equivalent plane, and
the matrix material includes one or more of ZnS, ZnO, ZnSe, and ZnTe.

14. The quantum dot layer according to claim 1,
wherein the matrix material includes a first single crystal portion in contact with the first quantum dot and a second single crystal portion in contact with the second quantum dot.

15. The quantum dot layer according to claim 14,
wherein the matrix material includes an amorphous body located between the first single crystal portion and the second single crystal portion.

16. A display device comprising a light-emitting element including a quantum dot layer,
wherein the quantum dot layer includes a first quantum dot and a second quantum dot each having a surface, 80% or more of which is occupied by a region constituted by one type of equivalent crystal plane; and
a matrix material filling a space between the first quantum dot and the second quantum dot and being lattice-matched at an interface with the region.

17. (canceled)

18. (canceled)

19. A method for manufacturing a light-emitting element, the method comprising:
applying, onto an underlayer, a quantum dot solution including a quantum dot having a surface, 80% or more of which is occupied by a region constituted by one type of equivalent quantum plane and having a first lattice constant, a precursor, and a solvent; and
modifying the precursor to cause a matrix material to be epitaxially grown on the region, the matrix material having a second lattice constant that is from 95% to 105% of the first lattice constant.
